(19) United States
(12) Patent Application Publication
(10) Pub. No.: US 2014/0320163 A1
(43) Pub. Date: Oct. 30, 2014

(54) METHOD FOR MONITORING A PUMP

(71) Applicant: Daimler AG, Stuttgart (DE)

(72) Inventors: Andreas Haensel, Leinfelden (DE); Clemens Schwab, Wendlingen (DE)

(21) Appl. No.: 14/362,965

(22) PCT Filed: Oct. 19, 2012
(86) PCT No.: PCT/EP2012/004399

§ 371 Date: Jun. 5, 2014

(30) Foreign Application Priority Data
Dec. 9, 2011 (DE) 10 2011 120 686.1

(51) Int. Cl. G01R 31/34

(52) U.S. Cl. CPC G01R 31/34
USPC 324/765.01

(57) ABSTRACT

A method for monitoring the functioning of an electric motor-driven pump (1), preferably in a vehicle (F), which has an internal electronics system (4) by means of which functional parameters of the pump (1) are monitored. The internal electronic system (4) relays the values of the functional parameters to a central control device (8) via an internal communication interface (6), and the values of the functional parameters are detected and monitored in the central control device (8) with respect to critical limiting values. The change over time of at least one value of the functional parameters is detected in the central control device (8), and a malfunction of the pump (1) is deduced if a value of at least one functional parameter remains constant over a predefined period of time.

The invention relates to a method for monitoring the functioning of an electric motor-driven pump of the type defined in greater detail in the preamble of Claim 1. The invention further relates to the use of such a method.

Electric motor-driven pumps are used in many systems, in particular in motor vehicles, in which they are utilized for conveying media, for example cooling water. In particular for such pumps which are used for conveying media, in particular cooling media, it is important that their functioning is continuously monitored to be able to quickly respond to any malfunctions or failures, for example to be able to prevent overheating of components that are cooled by the cooling medium which is conveyed by the pump.

It is known from the general prior art and is customary for electric motor-driven pumps to have an internal electronics system which is typically designed as an electronics system for controlling the electric motor drive. This internal electronics system also monitors functional parameters of the pump and generates corresponding values of this monitoring. In particular for use in vehicles, it is now customary for the internal electronics system of this type of electric motor-driven pump to be connected to an internal communication interface, which in turn is connected to a central control device. In customary automotive applications, this is typically a connection of the control device to various components via a data bus, the mentioned internal communication interface being situated in the area of the data bus for each of the components. For the monitoring of the electric motor-driven pump, the internal electronics system transmits values of the functional parameters to the internal communication interface, which in turn relays these values to the central control device, which monitors the values of the functional parameters with regard to critical limiting values. If the values of the functional parameters are above or below critical limiting values, a malfunction of the pump may be deduced, and appropriate measures such as switching off the pump, shutting down the entire system, or the like may be initiated to avoid further damage and possible safety-relevant hazard situations.

The problem with this type of monitoring, which is generally known and customary, is that in the event of a failure of the supply voltage for the pump and a continuing supply voltage for the internal communication interface and the data bus, and thus typically also for the central control device, the values last transmitted from the internal electronics system of the electric motor-driven pump to the internal communication interface continue to be maintained in the area of the communication interface, and are continuously transmitted to the central control device. Since these values lie within the predefined limiting values, in this situation in which the internal electronics system of the pump has failed, the failure of the pump is not recognized. This may result in safety-relevant problem situations, for example overheating of components which should have been cooled by the cooling medium which is conveyed by the electric motor-driven pump.

Of course, it is possible to monitor the functioning of the pump via additional internal sensors. However, this is comparatively complex and costly, and is not desired in particular for use in a vehicle due to costs and the typical customary installation situation.

The object of the present invention is to provide a method for monitoring the functioning of this type of electric motor-driven pump, which easily and efficiently ensures secure and reliable monitoring of the pump.

This object is achieved according to the invention by the method having the features in the characterizing part of Claim 1. Advantageous embodiments of the method according to the invention result from the subclaims which are dependent on Claim 1. Furthermore, a particularly preferred use of the method according to the invention is set forth in Claim 7. Advantageous embodiments of this use result from the subclaims which are dependent on Claim 7.

In the method according to the invention for monitoring the functioning of the electric motor-driven pump in the manner described above, in addition to monitoring of the values of the functional parameters with regard to being above or below limiting values, it is provided that the change over time of at least one value of the functional parameters is detected in the central control device. If at least one value of the functional parameters does not change over a predefined period of time, a malfunction in the pump may likewise be deduced. Due to the dynamic processes in the pump, the functional parameters will always fluctuate during normal operation of the pump. However, if the rotational speed required by the system is not supposed to change over a certain period of time, a change is forced in the range which does not disturb the system but which must trigger a change in the reported values. If no fluctuations in the values of the functional parameters are determined over a predefined period of time, it must be assumed that the transmitted values do not correspond to reality. In this case, the internal electronics system has presumably become disabled due to, for example, a power failure in the area of the pump itself, so that the internal communication interface continues to relay to the central control device the constant values which the internal communication interface last obtained from the internal electronics system.

Thus, if the values remain constant over a predefined period of time, a malfunction is present, either in the pump, or at least in the area of the internal electronics system or the communication between the internal electronics system and the internal communication interface. In this situation, a malfunction is thus likewise indicated which requires appropriate countermeasures, for example shutting down the system, outputting an acoustic and/or visual warning, or the like. The method according to the invention uses only a few extra programming steps in the software of the central control device, so that additional sensors, monitoring and evaluation of the measured data delivered by the sensors, and the like may be dispensed with. The design is thus simple and efficient, and may be easily retrofitted in existing systems by updating the software of the control device.

One particularly preferred use of the method according to the invention is for the monitoring of a media pump in a vehicle. In particular for automotive applications, reliability in the conveying of media, in particular a cooling medium for cooling at least one component, plays an important role. At the same time, systems in vehicles should be simple, efficient, and very reliable. Therefore, the method according to the invention is particularly well suited here, since it is able to implement the additional monitoring function for the electric motor-driven pump without the additional complexity of the sensor system, lines to be laid, and the like.

In another advantageous use of the method according to the invention, it is also provided that the vehicle is an electrically driven vehicle, in particular a vehicle having a fuel cell system. In particular in such vehicles, the supply of media, in particular the cooling in the present context, to the fuel cell via electric motor-driven pumps is generally known and customary. At the same time, the supply of media is very important, since it is responsible for good functionality and a comparatively long service life of the components of the fuel cell system, which are presently comparatively expensive. Due to the simple and efficient design, in a compactly implemented and easily controllable system a high degree of reliability may thus be achieved for the system and also for the passengers of such a vehicle who come into contact with the system.

Further advantageous embodiments of the method according to the invention and of the use of the method according to the invention result from the other dependent claims, and also become clear based on the exemplary embodiment, which is described in greater detail below with reference to the figures.

The figures show the following:

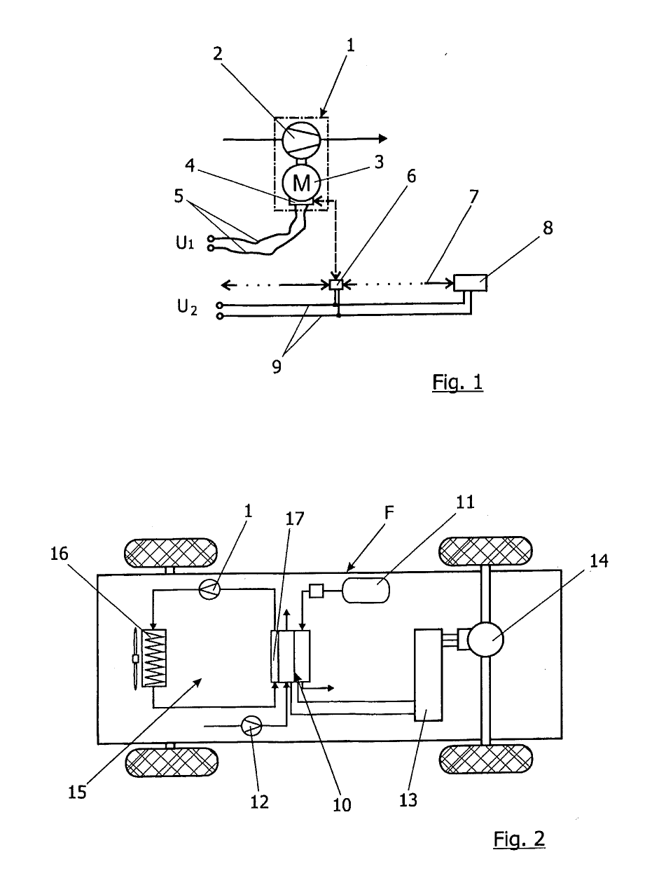

FIG. 1 shows a schematic illustration of a design for carrying out the method according to the invention; and

FIG. 2 shows an example of a vehicle in which the method according to the invention may be used.

An electric motor-driven pump 1 is apparent in the illustration in FIG. 1. This pump is composed essentially of the components bordered by the dash-dotted line. The conveying device 2 and the electric motor 3 are important components of the electric motor-driven pump, and are typically connected to one another via a shaft. For supplying power to the electric motor-driven pump 1, an internal electronics system 4 is connected to a first voltage source U₁ via two indicated line elements 5. In addition, the functioning of the electric motor-driven pump 1 is monitored via this internal electronics system 4 in a manner known per se. For this purpose, various functional parameters are detected. The values of the functional parameters are then relayed to an internal communication interface 6, as indicated by the dashed-line double arrow. This internal communication interface 6 is connected to a data bus 7, for example a CAN bus or a LIN bus. Of course, other data bus systems may also be used. Control and monitoring then take place via a central control device 8, which typically is connected not only to the internal communication interface 6 of the pump 1, but also to other components. For supplying power, the internal communication interface 6 is connected to a second voltage source U₂ via two indicated line elements 9.

As previously mentioned, values of functional parameters are detected and transmitted to the internal communication interface 6 via the internal electronics system 4 of the pump 1. The internal communication interface then relays the values to the central control device 8. These values are compared to predefined limiting values in the area of the central control device 8. As soon as one of the values is outside the predetermined limits for secure and reliable functioning of the pump 1, the central control device 8 initiates appropriate countermeasures, up to emergency shutdown of the entire system. This monitoring of the functioning of the pump 1 corresponds to the prior art.

Situations may occur in which the internal communication device 6 reports its stored values to the control device 8 via the data bus 7, even if the internal electronics system 4 of the pump 1 is no longer delivering instantaneous values, for example due to a failure of the first voltage source U₁. The central control device 8 then continues to receive these values, which are within the predefined limiting values, last delivered by the internal electronics system 4 and transmitted by the internal communication device 6. It is thus assumed that the pump 1 is operating properly, which is not, or does not necessarily have to be, the case. To counteract this problem of an erroneous assessment that the pump 1 is functioning properly, the control device 8 now monitors the changes over time of the values of the functional parameters which are transmitted by the internal communication interface 6 to the central control device 8. In reality, flow dynamic processes in the conveyed medium and the like will continuously result in a change in the relevant parameters in the area of the pump 1. Thus, the values of the functional parameters must also continuously change in the area of the central control device 8. If these values remain constant over a predefined period of time, it must be assumed that these values have not been detected by the internal electronics system 4 of the pump 1, but instead are relayed by the interface 6 in the absence of existing communication between the internal communication interface 6 and the pump 1, since in the event of a failure of the pump 1 with a continuing voltage supply to the control voltage U₂, the internal communication interface continues to transmit the values last obtained from the pump 1, provided that they have not been overwritten by other values. By monitoring the change over time of the transmitted values, such a situation may now be detected in the central control device 8, since an absence of the change over time of the values in the area of the central control device 8 allows the conclusion to be drawn that there is a disturbance in the communication between the internal communication interface 6 and the pump 1. Such a disturbance could possibly be a failure of the pump 1, for example due to the response of an overload protection system of the pump 1 in the area of its main power supply. An appropriate response must be made to such an event, for example by an emergency shutdown, outputting a warning to the user, or the like.

A particularly favorable and advantageous use for the monitoring of the electric motor-driven pump 1 is indicated in the illustration in FIG. 2. The illustration in FIG. 2 indicates, strictly by way of example, a vehicle F which in the illustrated exemplary embodiment is designed as a fuel cell vehicle. This vehicle includes a fuel cell system having a fuel cell 10. This fuel cell 10 is provided with hydrogen from a pressure tank 11, and with air-oxygen via an air conveying line 12. The generated electrical power is received by a traction motor 14, for example, via a power electronics system 13. The fuel cell 10 is typically cooled by a cooling circuit 15, indicated here in a greatly simplified and schematic manner, by means of a cooling medium. The cooling medium is circulated in the cooling circuit 15 via the electric motor-driven pump 1, and flows through a vehicle radiator 16, in the region of which the cooling medium is cooled, and flows through a heat exchanger 17 in the area of the fuel cell 10 in which it absorbs waste heat of the fuel cell 10. In particular for such a cooling circuit, which in principle could of course also be situated in a vehicle driven by an internal combustion engine, the use of the method according to the invention for monitoring the functioning of the electric motor-driven pump 1 is particularly advantageous. This is true in particular due to the fact that, as a result of the method according to the invention, an additional sensor system, additional line elements to be laid, and the like for reliable monitoring of the functioning of the pump 1 may be dispensed with entirely. On the other hand, due to the reliable monitoring of the functioning of the pump 1, a malfunction in the cooling circuit 1, which typically would result in overheating of the fuel cell 10, may be securely and reliably ruled out. The fuel cell 10 may thus be protected so that it achieves a longer service life. In addition, critical situations or critical temperatures in the area of the fuel cell 10, in which hydrogen and oxygen are present during regular operation, may be prevented. This results in a very safe vehicle F which may be easily and cost-effectively designed so that it is very safe for its passengers.

1. A method for monitoring the functioning of an electric motor-driven pump (1) which has an internal electronics system (4) by means of which functional parameters of the pump (1) are monitored, comprising:
using the internal electronic system (4) to relay the values of the functional parameters to a central control device (8) via an internal communication interface (6),
detecting and monitoring the values of the functional parameters in the central control device (8) with respect to critical limiting values,
detecting the change over time of at least one value of the functional parameters in the central control device (8), and
deducing a malfunction of the pump (1) if a value of at least one functional parameter remains constant over a predefined period of time.

2. The method according to claim 1, wherein the change over time of all values of the functional parameters is detected.

3. The method according to claim 1, wherein the internal communication interface (6) and the pump (1) are supplied from different voltage sources (U₁, U₂).

4. The method according to claim 3, wherein the internal communication interface (6) and the central control device (8) are supplied from the same voltage source (U₂).

5. The method according to claim 1, wherein the relaying of the values between the internal communication interface (6) and the central control device (8) takes place via a data bus (7).

6. The method according to claim 5, wherein the data bus (7) is designed as a CAN bus or LIN bus.

7. The method according to claim 1, wherein the pump (1) is a media pump (1) in a vehicle (F).

8. The method according to claim 7, wherein the media is a cooling medium for cooling at least one component (10).

9. The method according to claim 7, wherein the media is a cooling medium in a cooling circuit (15) for cooling drive components and/or energy generation components (10) of the vehicle (9).

10. The method according to claim 7, wherein the vehicle (F) is an electrically driven vehicle.

11. The method according to claim 10, wherein the vehicle (F) is an electrically driven vehicle having a fuel cell system.
